(19) United States
(12) Patent Application Publication
(10) Pub. No.: US 2025/0311557 A1
(43) Pub. Date: Oct. 2, 2025

(54) DISPLAY DEVICE AND MANUFACTURING METHOD OF THE SAME

(71) Applicant: Samsung Display Co., LTD., Yongin-si (KR)

(72) Inventor: HYUNEOK SHIN, Yongin-si (KR)

(21) Appl. No.: 19/033,349

(22) Filed: Jan. 21, 2025

(30) Foreign Application Priority Data
Apr. 2, 2024 (KR) 10-2024-0044570

(51) Int. Cl. H10K 59/122; H10K 59/12; H10K 59/38; H10K 102/00

(52) U.S. Cl. CPC H10K 59/122; H10K 59/1201; H10K 59/38; H10K 2102/331

(57) ABSTRACT

A display device includes: a base layer including light-emitting regions and a non-light-emitting region adjacent to the light-emitting regions; a pixel-defining layer including light-emitting openings respectively overlapping the light-emitting regions and on the base layer; first to third light-emitting elements each including a first electrode in the light-emitting opening, a second electrode, and a light-emitting pattern between the first electrode and the second electrode, and configured to provide source light having the same color; a partition wall including partition wall openings respectively overlapping the light-emitting openings and on the pixel-defining layer; an encapsulation layer including capping patterns each inside the partition wall opening and covering the second electrode; and a color control layer including color control patterns, which are each inside the partition wall opening and of which at least any one includes a quantum dot (QD).

### CROSS-REFERENCE TO RELATED APPLICATIONS

The present application claims priority to and the benefit of Korean Patent Application No. 10-2024-0044570, filed on Apr. 2, 2024, the entire disclosure of which is hereby incorporated by reference.

### BACKGROUND

### 1. Field

Aspects of some embodiments of the present disclosure herein relate to a display device.

### 2. Description of the Related Art

A display device includes a plurality of pixels and a driving circuit (e.g., a scan driving circuit and a data driving circuit) for controlling the plurality of pixels. The plurality of pixels each include a display element and a pixel driving circuit for controlling the display element. The pixel driving circuit may include a plurality of transistors which are organically connected and at least one capacitor.

The above information disclosed in this Background section is only for enhancement of understanding of the background and therefore the information discussed in this Background section does not necessarily constitute prior art.

### SUMMARY

Aspects of some embodiments of the present disclosure herein relate to a display device, and for example, to a display device including a display element having relatively improved reliability. Aspects of some embodiments of the present disclosure herein also relate to a manufacturing method of a display device having a relatively simplified process.

Aspects of some embodiments of the present disclosure include a display device having relatively improved display quality. Aspects of some embodiments of the present disclosure also include a manufacturing method of a display device having a relatively simplified manufacturing process.

Aspects of some embodiments of the present disclosure include a display device including a base layer including light-emitting regions and a non-light-emitting region adjacent to the light-emitting regions, a pixel-defining layer including light-emitting openings respectively overlapping the light-emitting regions and on the base layer, first to third light-emitting elements each including a first electrode in the light-emitting opening, a second electrode, and a light-emitting pattern between the first electrode and the second electrode, and providing source light having the same color, a partition wall including partition wall openings respectively overlapping the light-emitting openings and on the pixel-defining layer, an encapsulation layer including capping patterns each inside the partition wall opening and covering the second electrode, and a color control layer including color control patterns which are each inside the partition wall opening and of which at least any one includes a quantum dot (QD).

According to some embodiments, the partition wall may include a lower layer on the pixel-defining layer and an upper layer on the lower layer, and the lower layer may include aluminum, and the upper layer may include titanium.

According to some embodiments, the display device may further include an organic pattern on the upper layer, and the organic pattern may have liquid repellency.

According to some embodiments, a portion of an upper surface of the organic pattern may be exposed from the color control patterns.

According to some embodiments, another portion of the upper surface of the organic pattern may be covered with the color control patterns.

According to some embodiments, the display device may further include a passivation layer on the partition wall and the color control layer and including an inorganic material.

According to some embodiments, the color control patterns may be spaced apart from each other on the upper surface of the organic pattern, and the portion of the organic pattern exposed between the color control patterns may be in contact with the passivation layer.

According to some embodiments, the display device may further include a color filter layer including a black matrix including light blocking openings overlapping the partition wall openings and color filter patterns each in the light blocking opening and overlapping the color control patterns, the color filter layer being on the passivation layer.

According to some embodiments, the display device may further include a window on the color filter layer and an adhesive layer between the color filter layer and the window.

According to some embodiments, a portion of an upper surface of the organic pattern may be covered with the capping patterns, and the color control patterns may be in contact with each other on another portion, exposed by the capping patterns, of the upper surface of the organic pattern.

According to some embodiments, the light-emitting patterns and the organic pattern may include the same material.

According to some embodiments, the source light may have a blue color.

According to some embodiments, the second electrodes may be electrically connected by being in contact with a side surface of the lower layer.

According to some embodiments, the display device may include pixel circuits between the base layer and the pixel-defining layer and connected to the first to third light-emitting elements, wherein the pixel circuits may each include three transistors and a capacitor connected to the transistors.

According to some embodiments, the pixel-defining layer may include an inorganic material.

According to some embodiments of the present disclosure, a manufacturing method of a display device includes forming, on a base layer, a pixel-defining layer having light-emitting openings defined therein, the light-emitting openings exposing first electrodes, forming, on the pixel-defining layer, a partition wall having partition wall openings defined therein, the partition wall openings overlapping the light-emitting openings, forming a light-emitting organic layer on the first electrodes and the partition wall, forming a second electrode on the light-emitting organic layer, forming an encapsulation layer covering the second electrode and the partition wall openings, forming photoresist patterns on the encapsulation layer overlapping the partition wall openings, removing the encapsulation layer on the partition wall, exposing the light-emitting organic layer on the partition wall by removing the second electrode on the partition wall, and forming color control patterns inside the partition wall openings.

According to some embodiments, the light-emitting organic layer on the partition wall may have liquid repellency.

According to some embodiments, the partition wall may include a lower layer on the pixel-defining layer and an upper layer on the lower layer, and the lower layer may include aluminum, and the upper layer may include titanium.

According to some embodiments, the removing of the encapsulation layer may be performed through a dry etching process, and the removing of the second electrode may be performed through a wet etching process.

According to some embodiments, the forming of the color control patterns may be performed through an inkjet printing method.

Aspects of some embodiments of the present disclosure include a display device displays an image based on input image data provided from the processor and a driving unit drives the display panel based on the input image data and a brightness value of the display panel, and the display panel including a base layer including light-emitting regions and a non-light-emitting region adjacent to the light-emitting regions, a pixel-defining layer including light-emitting openings respectively overlapping the light-emitting regions and on the base layer, first to third light-emitting elements each including a first electrode in the light-emitting opening, a second electrode, and a light-emitting pattern between the first electrode and the second electrode, and providing source light having the same color, a partition wall including partition wall openings respectively overlapping the light-emitting openings and on the pixel-defining layer, an encapsulation layer including capping patterns each inside the partition wall opening and covering the second electrode, and a color control layer including color control patterns which are each inside the partition wall opening and of which at least any one includes a quantum dot (QD).

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1A is a perspective view of a display device according to some embodiments of the present disclosure;

FIG. 1B is a perspective view of a curved display device according to some embodiments of the present disclosure;

FIG. 2A is a cross-sectional view of a display device according to some embodiments of the present disclosure;

FIG. 2B is a plan view of a display device according to some embodiments of the present disclosure;

FIG. 3 is an equivalent circuit diagram of a pixel according to some embodiments of the present disclosure;

FIG. 4A is an enlarged plan view of a display region according to some embodiments of the present disclosure;

FIG. 4B is an enlarged plan view of a display region according to some embodiments of the present disclosure;

FIG. 5 is a cross-sectional view taken along the line I-I′ of FIG. 4B;

FIG. 6 is an enlarged cross-sectional view of one region of FIG. 5;

FIG. 7 is a cross-sectional view of a display device according to some embodiments of the present disclosure;

FIG. 8 is a cross-sectional view of a display device according to some embodiments of the present disclosure; and

FIGS. 9A to 9M are cross-sectional views of a manufacturing method of a display device according to some embodiments of the present disclosure.

### DETAILED DESCRIPTION

In this specification, it will be understood that when an element (or a region, a layer, a portion, or the like) is referred to as being “on”, “connected to” or “coupled to” another element, it may be directly located on, connected or coupled to the other element, or an intervening element may be located therebetween.

Like reference numerals or symbols refer to like elements. Also, in the drawings, the thicknesses, ratios, and dimensions of the elements are exaggerated for effective description of the technical contents. The term “and/or” includes all of one or more combinations which may be defined by related elements.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well unless the context clearly indicates otherwise.

Also, terms such as “below”, “on lower side”, “above”, and “on upper side” may be used to describe the relationships of the elements illustrated in the drawings. These terms have relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, aspects of some embodiments of the present disclosure will be described in more detail with reference to the drawings.

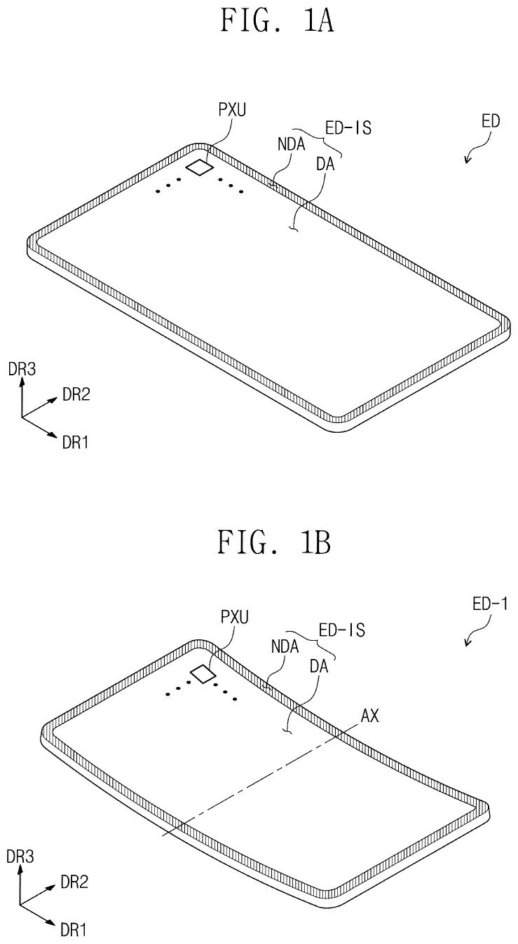

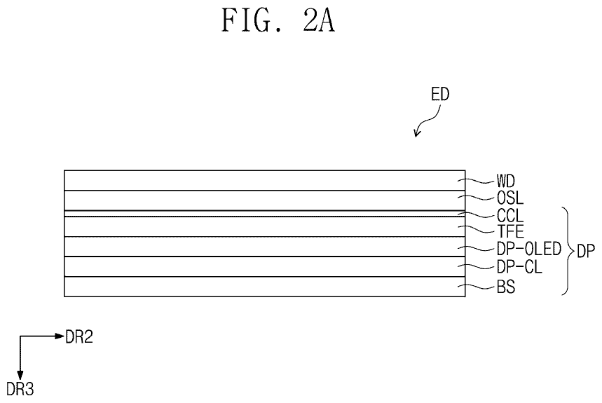

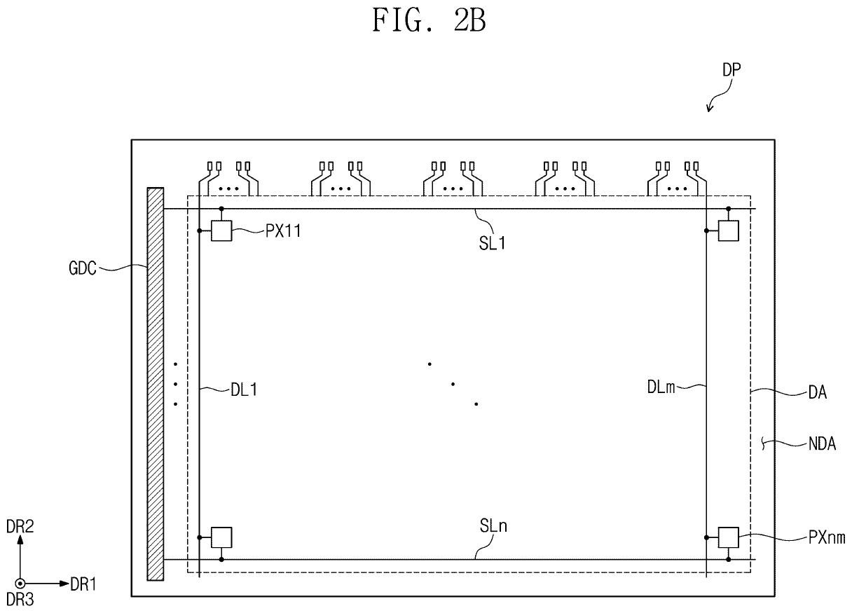

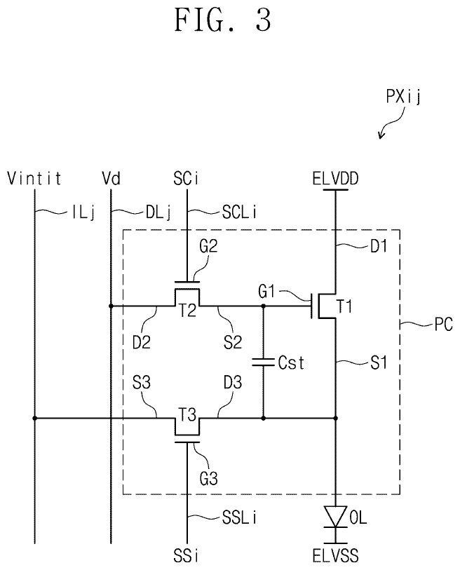

FIG. 1A is a perspective view of a display panel according to some embodiments of the present disclosure. FIG. 1B is a perspective view of a curved display panel according to some embodiments of the present disclosure. FIG. 2A is a cross-sectional view of a display panel according to some embodiments of the present disclosure. FIG. 2B is a plan view of a display panel according to some embodiments of the present disclosure. FIG. 3 is an equivalent circuit diagram of a pixel according to some embodiments of the present disclosure. Although FIG. 3 illustrates various components in a pixel circuit according to some embodiments, embodiments according to the present disclosure are not limited thereto, and according to some embodiments, the pixel circuit may include additional components or fewer components without departing from the spirit and scope of embodiments according to the present disclosure.

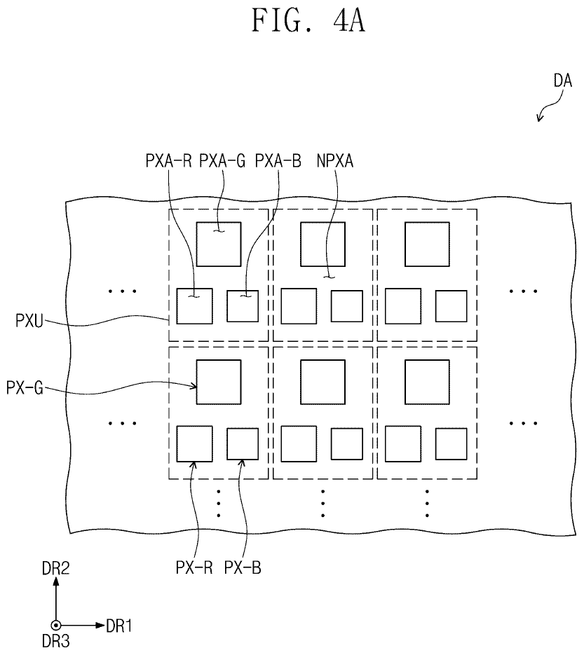

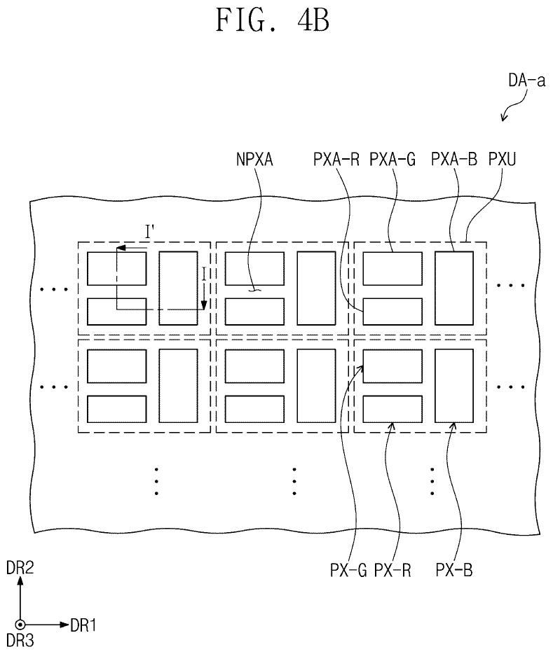

FIG. 4A is an enlarged plan view of a display region according to some embodiments of the present disclosure. FIG. 4B is an enlarged plan view of a display region according to some embodiments of the present disclosure.

A display device ED or ED-1 illustrated in FIG. 1A or FIG. 1B may be an emissive display panel and may be any one among a liquid crystal display panel, an electrophoretic display panel, a microelectromechanical system (MEMS) display panel, an electrowetting display panel, an organic light-emitting display panel, an inorganic light-emitting display panel, and a quantum dot display panel.

In addition, the display device ED or ED-1 according to some embodiments of the present disclosure may include an ultrasmall light-emitting element. For example, the display device ED or ED-1 may include a micro-LED element and/or a nano-LED element, but embodiments of the present disclosure are not particularly limited thereto.

Referring to FIG. 1A, the display device ED may display an image through a display surface ED-IS. An upper surface of a member located on the uppermost side of the display device ED may be defined as the display surface ED-IS. According to some embodiments of the present disclosure, an upper surface of a window panel WD illustrated in FIG. 2A may be provided as the display surface ED-IS of the display device ED.

The display surface ED-IS may be parallel to a plane defined by a first direction DR1 and a second direction DR2. A normal direction of the display surface ED-IS, that is a thickness direction of the display device ED, indicates a third direction DR3. A front surface (or an upper surface) and a rear surface (or a lower surface) of each layer or unit to be described below are distinguished from each other on the basis of the third direction DR3.

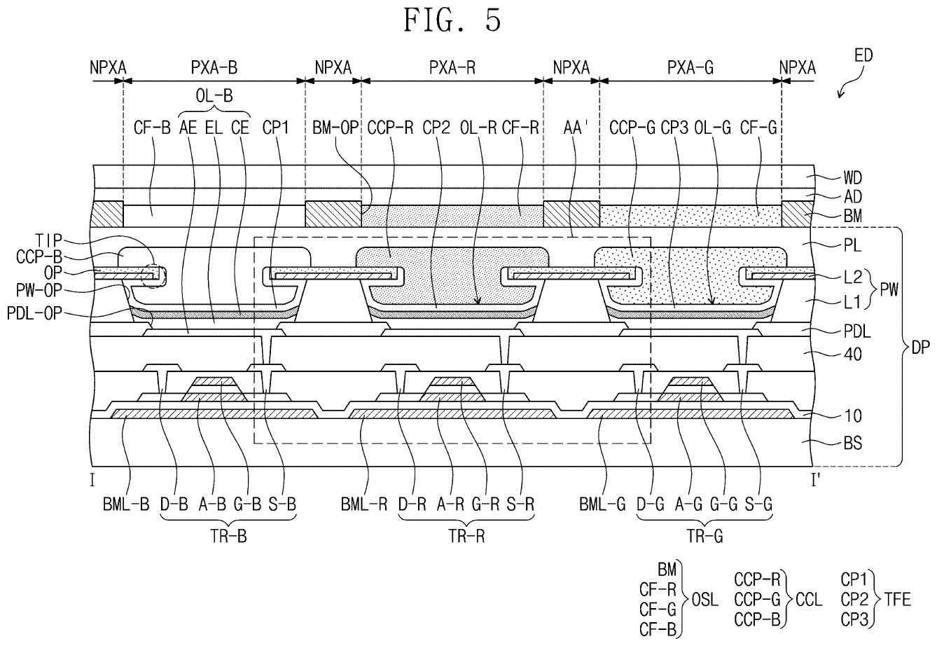

The display device ED may include a display region DA and a non-display region NDA. Light-emitting patterns EL (see FIG. 5) included in a pixel PXnm (see FIG. 2B) are located in the display region DA, and the light-emitting patterns EL (see FIG. 5) of the pixel PXnm (see FIG. 2B) are not located in the non-display region NDA. The non-display region NDA is defined along an edge of the display surface ED-IS. The non-display region NDA may surround (e.g., in a periphery or outside a footprint of) the display region DA. According to some embodiments of the present disclosure, the non-display region NDA may be omitted or located on only one side of the display region DA.

Referring to FIG. 1B, the display device ED-1 according to some embodiments may be curved along a first direction DR1 with respect to a virtual axis AX extending in a second direction DR2. However, embodiments of the present disclosure are not limited thereto, and an axis may extend in the first direction DR1, or the display device ED-1 may be curved with respect to a plurality of axes extending in different directions.

The display device ED or ED-1 according to some embodiments may be a rollable display panel, a foldable display panel, or a slidable display panel. Here, the display device ED and ED-1 may have a flexible property and may be capable of being folded or rolled while being installed on a display device. Accordingly, the display device ED or ED-1 may include a curved display surface or a stereoscopic display surface ED-IS. The stereoscopic display surface ED-IS may include a plurality of display regions which indicate different directions.

FIGS. 1A and 1B each illustrate that a unit pixel PXU is located in a display region DA. The unit pixel PXU may include at least two pixels that provide different light. For example, the unit pixel PXU may be a region in which pixels that provide source light are located. An emission area, shape, and arrangement of each of pixels 1 included in the unit pixel PXU are not limited to any one emission area, shape, and arrangement. For example, respective emission areas of the pixels included in the unit pixel PXU may be different from each other. In addition, each light-emitting region may have a circular or polygonal shape in a plan view.

Referring to FIGS. 2A and 2B, a display device ED according to some embodiments of the present disclosure may include a display panel DP, a color filter layer OSL, and a window panel WD. The display panel DP may include a base layer BS, a circuit element layer DP-CL located on the base layer BS, a display element layer DP-OLED, an encapsulation layer TFE, and a color control layer CCL located on the encapsulation layer TFE.

The circuit element layer DP-CL includes at least a plurality of insulating layers and a circuit element. Insulating layers to be described below may include an organic layer and/or an inorganic layer.

The base layer BS may include a synthetic resin film. The synthetic resin film may include a thermosetting resin. In particular, the synthetic resin film may include at least any one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite material substrate, or the like.

In the circuit element layer DP-CL, an insulating layer, a semiconductor layer, and a conductive layer are formed through coating, deposition, etc. Then, the insulating layer, the semiconductor layer, and the conductive layer may be selectively patterned through photolithography and etching process. Through such processes, a semiconductor pattern, a conductive pattern, a signal line, etc., are formed. Patterns located on the same layer are formed through the same process.

The circuit element layer DP-CL includes a signal line or a driving circuit constituting a pixel PXij (see FIG. 3). The display element layer DP-OLED may include a partition wall PW (see FIG. 5), a pixel-defining layer PDL (see FIG. 5), and a light-emitting element OL (see FIG. 3) included in the pixel PXij (see FIG. 3).

The encapsulation layer TFE may be located on the display element layer DP-OLED and protect the light-emitting element OL (see FIG. 3). The encapsulation layer TFE may include a single-layered inorganic layer or sequentially stacked inorganic layers. The inorganic layers may protect the light-emitting element OL (see FIG. 3) from moisture and oxygen.

The color control layer CCL may include color control patterns capable of converting an optical property of source light generated from the light-emitting element OL (see FIG. 3). At least any one of the color control patterns may include a quantum dot.

The color filter layer OSL may include color filter patterns which allow light transmitted through the color control patterns to be selectively transmitted, and a black matrix including light blocking openings in which the color filter patterns are located. Further description thereof will be made later.

The window panel WD may be located on the color filter layer OSL and transmit, to the outside, an image which is provided from the display device ED. In the window panel WD, the display region DA and the non-display region NDA of the display surface ED-IS may be distinguished from each other as illustrated in FIG. 1A. A boundary between the display region DA and the non-display region NDA may be defined by a bezel pattern which is located below the window panel WD and absorbs light.

The window panel WD may include a base layer and functional layers located on the base layer. The functional layers may include a protective layer, an anti-fingerprint layer, etc. The base layer of the window panel WD may include glass, sapphire, plastic, or the like.

FIG. 2B illustrates a planar arrangement relationship of pixels PX11 to PXnm and signal lines SL1 to SLn and DL1 to DLm included in the display device ED. The 1 signal lines SL1 to SLn and DL1 to DLm may include a plurality of scan lines SL1 to SLn and a plurality of data lines DL1 to DLm.

The pixels PX11 to PXnm may be located in a display region DA. The pixels PX11 to PXnm are each connected to a corresponding scan line among the plurality of scan lines SL1 to SLn and a corresponding data line among the plurality of data lines DL1 to DLm. The pixels PX11 to PXnm may each include a pixel driving circuit and a light-emitting element. Various signal lines may be further included in the display device ED according to the configuration of the pixel driving circuit of the pixels PX11 to PXnm.

A gate driving circuit GDC may be located in a non-display region NDA. The gate driving circuit GDC may be integrated into the display device ED through an oxide silicon gate (OSG) driver circuit process or an amorphous silicon gate (ASG) driver circuit process.

FIG. 3 illustrates an example circuit diagram of one pixel PXij among the pixels PX11 to PXnm.

The pixel PXij may include a pixel circuit PC and a light-emitting element OL. The pixel circuit PC may include a plurality of transistors T1 to T3 and a capacitor Cst.

According to some embodiments of the present disclosure, any one pixel PXij may include double capacitor spaced apart from each other and connected with a conductive pattern. Description thereof will be made later.

The plurality of transistors T1 to T3 may be formed through a low temperature polycrystalline silicon (LTPS) process or a low temperature polycrystalline oxide (LTPO) process. First to third transistors T1 to T3 may each include either a silicon semiconductor or an oxide semiconductor. Here, the oxide semiconductor may include a crystalline or amorphous oxide semiconductor, and the silicon semiconductor may include amorphous silicon, polycrystalline silicon, etc., but is not limited to any one embodiment.

Hereinafter, the first to third transistors T1 to T3 will be described as N-type transistors, but embodiments of the present disclosure are not limited thereto. Thus, each of the first to third transistors T1 to T3 may be a P-type transistor or an N-type transistor according to signals applied thereto. Here, a source and a drain of the P-type transistor may respectively correspond to a drain and a source of the N-type transistor.

FIG. 3 illustrates the pixel PXij connected to an i-th scan line SCLi, an i-th sensing line SSLi, a j-th data line DLj, and a j-th initial line ILj.

The pixel circuit PC may include the first transistor T1 (a driving transistor), the second transistor T2 (a switching transistor), the third transistor T3 (a sensing transistor), and the capacitor Cst. However, the pixel circuit PC may further include an additional transistor and an additional capacitor, and is not limited to any one embodiment.

The light-emitting element OL may be an inorganic light-emitting element or an organic light-emitting element including an anode (a first electrode) and a cathode (a second electrode). An anode of the light-emitting element OL may receive a first voltage ELVDD through the first transistor T1, and a cathode of the light-emitting element OL may receive a second voltage ELVSS. The light-emitting element OL may emit light upon receiving the first voltage ELVDD and the second voltage ELVSS.

The first transistor T1 may include a drain D1 which receives the first voltage ELVDD, a source S1 which is connected to the anode of the light-emitting element OL, and a gate G1 which is connected to the capacitor Cst. The first transistor T1 may control driving current flowing through the light-emitting element OL from the first voltage ELVDD in response to a voltage value stored in the capacitor Cst.

The second transistor T2 may include a drain D2 which is connected to the j-th data line DLj, a source S2 which is connected to the capacitor Cst, and a gate G2 which receives an i-th first scan signal SCi. The second transistor T2 provides a data voltage Vd to the first transistor T1 in response to the i-th first scan signal SCi.

The third transistor T3 may include a source S3 which is connected to the j-th initial line ILj, a drain D3 which is connected to the anode of the light-emitting element OL, and a gate G3 which receives an i-th second scan signal SSi. The j-th initial line ILj may receive an initial voltage Vintit.

The capacitor Cst may store voltage differences of various values according to an input signal. For example, the capacitor Cst may store a voltage equivalent to a difference between a voltage transmitted from the second transistor T2 and the first voltage ELVDD.

As illustrated in FIG. 4A, light generated from a first pixel PX-R may be provided to a first light-emitting region PXA-R, light generated from a second pixel PX-G may be provided to a second light-emitting region PXA-G, and light generated from a third pixel PX-B may be provided to a third light-emitting region PXA-B. The first to third light-emitting regions PXA-R, PXA-G, and PXA-B may correspond to light-emitting openings PDL-OP defined in a pixel-defining layer PDL to be described with reference to FIG. 5.

A non-light-emitting region NPXA is located between the first light-emitting region PXA-R, the second light-emitting region PXA-G, and the third light-emitting region PXA-B. The non-light-emitting region NPXA sets boundaries of the first to third light-emitting regions PXA-R, PXA-G, and PXA-B and prevents or reduces color mixing between the first to third light-emitting regions PXA-R, PXA-G, and PXA-B.

The first to third pixels PX-R, PX-G, and PX-B may each include a light-emitting element OL (see FIG. 5), and the first to third pixels PX-R, PX-G, and PX-B may generate source light having the same color. However, emission areas of the first to third pixels PX-R, PX-G, and PX-B may be the same or may be different.

Source light generated from the light-emitting elements of the first to third pixels PX-R, PX-G, and PX-B is converted into light having different colors and emitted through the first light-emitting region PXA-R, the second light-emitting region PXA-G, and the third light-emitting region PXA-B. The source light that is emitted may be 1 converted into any one among red, green, and blue light through the color control patterns included in the color filter layer OSL described with reference to FIG. 2A.

Referring to FIG. 4A, the first light-emitting region PXA-R and the third light-emitting region PXA-B are located in the same row, and the second light-emitting region PXA-G is located in a row different from the row in which the first light-emitting region PXA-R and the third light-emitting region PXA-B are located. For example, the first light-emitting region PXA-R and the third light-emitting region PXA-B may be arranged to be spaced apart from each other along a first direction DR1, and the second light-emitting region PXA-G may be arranged to be spaced apart from the first light-emitting region PXA-R and the third light-emitting region PXA-B in respective diagonal directions of the first direction DR1 and a second direction DR2.

According to some embodiments, an area of the first light-emitting region PXA-R may be smaller than an area of the second light-emitting region PXA-G and greater than an area of the third light-emitting region PXA-B.

According to some embodiments, the first light-emitting region PXA-R, the second light-emitting region PXA-G, and the third light-emitting region PXA-B having square shapes are illustrated as an example, but an arrangement and area of the light-emitting regions are not limited thereto.

An arrangement structure of the first light-emitting region PXA-R, the second light-emitting region PXA-G, and the third light-emitting region PXA-B in a unit pixel PXU illustrated in FIG. 4A is merely one example, and embodiments of the present disclosure are not limited thereto. According to some embodiments of the present disclosure, the first light-emitting region PXA-R, the second light-emitting region PXA-G, and the third light-emitting region PXA-B may be arranged along the first direction DR1 and located in the same row. Also, arrangements of the first light-emitting region PXA-R, the second light-emitting region PXA-G, and the third light-emitting region PXA-B in respective unit pixels PXU do not necessarily need to be the same.

FIG. 4B is an enlarged plan view of a display region according to some embodiments of the present disclosure.

Referring to FIG. 4B, light generated from a first pixel PX-R may be provided to a first light-emitting region PXA-R, light generated from a second pixel PX-G may be provided to a second light-emitting region PXA-G, and light generated from a third pixel PX-B may be provided to a third light-emitting region PXA-B. The first to third light-emitting regions PXA-R, PXA-G, and PXA-B may correspond to light-emitting openings PDL-OP defined in a pixel-defining layer PDL to be described with reference to FIG. 5.

The first light-emitting region PXA-R and the second light-emitting region PXA-G may be located in the same column, and the third light-emitting region PXA-B may be located in a column different from the column in which the first light-emitting region PXA-R and the second light-emitting region PXA-G are located. For example, the first light-emitting region PXA-R and the second light-emitting region PXA-G may be arranged along a second direction DR2, and the third light-emitting region PXA-B may be arranged with the first light-emitting region PXA-R and the second light-emitting region PXA-G along a first direction DR1.

The first light-emitting region PXA-R and the second light-emitting region PXA-G may have rectangular shapes extending along the first direction DR1, and the third light-emitting region PXA-B may have a rectangular shape extending along the second direction DR2.

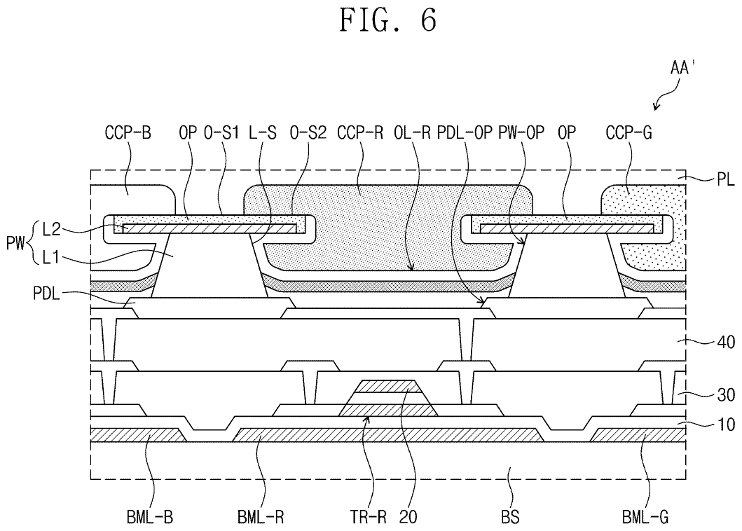

FIG. 5 is a cross-sectional view taken along line I-I′ of FIG. 4B. FIG. 6 is an enlarged cross-sectional view of one region of FIG. 5.

Referring to FIGS. 5 and 6, a display device ED according to some embodiments may include a display panel DP, a color filter layer OSL, and a window panel WD. An adhesive layer AD may be located between the color filter layer OSL and the window panel WD. The adhesive layer AD may bond the window panel WD and the color filter layer OSL. The adhesive layer AD may include a typical adhesive 1 such as a pressure sensitive adhesive (PSA), an optically clear adhesive (OCA), and an optical clear resin (OCR), but is not limited to any one embodiment.

As described with reference to FIG. 3, one pixel PXij (see FIG. 3) may include a light-emitting element OL-R, OL-G, or OL-B and a pixel circuit PC (see FIG. 3) connected thereto. FIG. 5 illustrates first transistors TR-R, TR-G, and TR-B included in respective pixels, and the first transistors TR-R, TR-G, and TR-B may correspond to the first transistor T1 described with reference to FIG. 3.

A base layer BS may provide a base surface on which a plurality of insulating layers 10 to 40 and the transistors TR-R, TR-G, and TR-B included in the circuit element layer DP-CL (see FIG. 2A) may be located. FIG. 5 illustrates a single-layered base layer, but embodiments of the present disclosure are not limited thereto. The base layer BS may be provided as a multi-layered base layer in which an organic layer and an inorganic layer are sequentially stacked, but is not limited to any one embodiment.

The circuit element layer DP-CL (see FIG. 2A) may be located on the base layer BS. The circuit element layer DP-CL (see FIG. 2A) may include the plurality of insulating layers 10 to 40, light blocking patterns BML-R, BML-G, and BML-B, and the transistors TR-R, TR-G, and TR-B.

The light blocking patterns BML-R, BML-G, and BML-B may be located on the base layer BS. The light blocking patterns BML-R, BML-G, and BML-B may include first to third light blocking patterns BML-R, BML-G, and BML-B spaced apart from each other.

The first light blocking pattern BML-R may overlap a first semiconductor pattern A-R and receive a bias voltage. The first light blocking pattern BML-R may receive the first voltage ELVDD (see FIG. 3). The first light blocking pattern BML-R may block electrical potential caused by polarization from affecting the first transistor TR-R. In addition, the first light blocking pattern BML-R may block external light from reaching the first transistor TR-R. According to some embodiments of the present 1 disclosure, the first light blocking pattern BML-R may be a floating electrode isolated from another electrode or line.

Description of the first light blocking pattern BML-R may also be applied to the second and third light blocking patterns BML-G and BML-B.

A first insulating layer 10 may cover the first to third light blocking patterns BML-R, BML-G, and BML-B and may be located on the base layer BS. The first insulating layer 10 may include an inorganic material. For example, the inorganic material may include a silicon oxide layer and a silicon nitride layer. The silicon oxide layer and the silicon nitride layer may be each provided in plurality, and the silicon oxide layers and the silicon nitride layers may be alternately stacked.

Semiconductor patterns A-R, A-G, and A-B may be located on the first insulating layer 10. The semiconductor patterns A-R, A-G, and A-B may each include an active, a source, and a drain constituting the semiconductor pattern A-R, A-G, or A-B. The active, the source, and the drain may be regions divided according to a doping concentration or conductivity of the semiconductor pattern.

A second insulating layer 20 may be located on the semiconductor patterns A-R, A-G, and A-B overlapping respective actives of the semiconductor patterns A-R, A-G, and A-B. The second insulating layer 20 may be located between the semiconductor patterns and gates G-R, G-G, and G-B. The second insulating layer 20 may expose a region except the actives A-R, A-G, and A-B of the semiconductor patterns. The second insulating layer 20 may be patterned using the gates G-R, G-G, and G-B as a mask. Thus, the second insulating layer 20 may have a shape of patterns spaced apart from each other.

According to some embodiments, the second insulating layer 20 may include an inorganic material. For example, the inorganic material may include a silicon oxide layer and a silicon nitride layer. The silicon oxide layer and the silicon nitride layer may be each provided in plurality, and the silicon oxide layers and the silicon nitride layers may be alternately stacked.

The gates G-R, G-G, and G-B may be located on the second insulating layer 20. According to some embodiments, the gates G-R, G-G, and G-B may include sequentially stacked metal layers. A first layer may include titanium, and a second layer may include copper.

A third insulating layer 30 may be located on the first insulating layer 10 and the second insulating layer 20 and cover the gates G-R, G-G, and G-B and the semiconductor patterns exposed from the gates G-R, G-G, and G-B. According to some embodiments, the third insulating layer 30 may include silicon oxynitride. However, embodiments of the present disclosure are not limited thereto, and the third insulating layer 30 may include an organic material.

First connection electrodes S-R, S-G, and S-B may be located on the third insulating layer 30. The first connection electrodes S-R, S-G, and S-B may be each connected to a corresponding source through a contact hole defined in the third insulating layer 30. According to some embodiments, the first connection electrodes S-R, S-G, and S-B may include sequentially stacked metal layers. A first layer may include titanium, a second layer may include copper, and a third layer may include indium tin oxide (ITO).

Second connection electrodes D-R, D-G, and D-B may be located on the third insulating layer 30. The second connection electrodes D-R, D-G, and D-B may be each connected to a corresponding drain through a contact hole defined in the third insulating layer 30. The second connection electrodes D-R, D-G, and D-B may be spaced apart from the first connection electrodes S-R, S-G, and S-B and may include the same material as the first connection electrodes S-R, S-G, and S-B.

A fourth insulating layer 40 may be located on the third insulating layer 30 and cover the first connection electrodes S-R, S-G, and S-B and the second connection electrodes D-R, D-G, and D-B. According to some embodiments, the fourth insulating layer 40 may include an organic material.

The display element layer DP-OLED (see FIG. 2A) may be located on the circuit element layer DP-CL (see FIG. 2A). The display element layer DP-OLED (see FIG. 2A) may include a pixel-defining layer PDL, a partition wall PW, light-emitting elements OL-R, OL-B, and OL-G, an encapsulation layer TFE, a color control layer CCL, and a passivation layer PL.

The pixel-defining layer PDL may be located on the circuit element layer DP-CL. According to some embodiments, the pixel-defining layer PDL may be an insulating film including an inorganic material. For example, the pixel-defining layer PDL may include silicon oxide, silicon nitride, or a combination thereof. For example, the pixel-defining layer PDL may have a double-layered structure in which a silicon oxide layer and a silicon nitride layer are sequentially stacked. However, this is described as an example, and a material of the pixel-defining layer PDL or whether the pixel-defining layer PDL is single-layered or multi-layered may be variously changed as long as the pixel-defining layer PDL is an insulating film including an inorganic material, and the pixel-defining layer PDL is not limited to any one embodiment.

According to some embodiments, the pixel-defining layer PDL may include first to third light-emitting openings PDL-OP. The first to third light-emitting openings PDL-OP may be formed by penetrating a portion of the pixel-defining layer PDL, the portion overlapping anodes AE respectively included in the light-emitting elements OL-R, OL-G, and OL-B. Thus, the first to third light-emitting openings PDL-OP may expose at least a portion of the anodes AE respectively included in the light-emitting elements OL-R, OL-G, and OL-B.

According to some embodiments, the partition wall PW may be located on the pixel-defining layer PDL. The partition wall PW may overlap a non-light-emitting region NPXA. The partition wall PW may include first to third partition wall openings PW-OP. The first to third partition wall openings PW-OP may be formed by penetrating the partition wall PW. The first to third partition wall openings PW-OP may respectively overlap corresponding first to third light-emitting openings PDL-OP.

Each of the first to third partition wall openings PW-OP may integrally form opening space with a corresponding light-emitting opening. Thus, a corresponding light-emitting element OL-R, OL-G, or OL-B may be located in the partition wall opening PW-OP and the light-emitting opening PDL-OP which are integrated with each other. In addition, the partition wall opening PW-OP and the light-emitting opening PDL-OP which are integrated with each other may expose at least a portion of a corresponding anode AE.

The partition wall PW according to some embodiments may include a first layer L1 (a lower layer) and a second layer L2 (an upper layer) located on the first layer L1. The first layer L1 may be located on the pixel-defining layer PDL.

The first layer L1 may include a conductive material. The conductive material may include metal, transparent conductive oxide (TCO), or a combination thereof. For example, the metal may include gold (Au), silver (Ag), aluminum (AI), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

According to some embodiments, the second layer L2 may include metal or non-metal. For example, the metal may include gold (Au), silver (Ag), aluminum (AI), magnesium (Mg), lithium (Li), molybdenum (Mo), titanium (Ti), copper (Cu), or an alloy. The non-metal may include silicon, silicon oxide, silicon nitride, silicon oxynitride, metal oxide, metal nitride, or a combination thereof, and the metal oxide may include transparent conductive oxide (TCO).

According to some embodiments, the partition wall PW may include a tip portion TIP. For example, the second layer L2 may relatively protrude in a direction toward a center of a corresponding light-emitting region (or a corresponding partition wall opening) compared to the first layer L1. In a cross-sectional view, a portion of the second layer L2, the portion further protruding toward a corresponding light-emitting region than the first layer L1, may be defined as the tip portion TIP. The tip portion TIP may be partially covered with the encapsulation layer TFE. The tip portion TIP formed in the partition wall PW may be formed because the partition wall PW is etched in an under-cut shape due to difference in etch rate of the first layer L1 and the second layer L2.

The light-emitting elements OL-R, OL-G, and OL-B may be each located inside a corresponding partition wall opening PW-OP. The light-emitting elements OL-R, OL-G, and OL-B may each include a cathode CE located on the anode AE and a light-emitting pattern EL located between the anode AE and the cathode CE.

According to some embodiments, the cathodes CE may be physically separated by the second layer L2 that forms the tip portion TIP and located in corresponding partition wall openings PW-OP. Accordingly, the cathodes CE may be spaced apart from each other with the partition wall PW therebetween. According to some embodiments of the present disclosure, the cathodes CE may be in contact with the first layer L1 of the partition wall PW, the first layer L1 including a conductive material, and thus may be electrically connected to each other and provided with a common voltage.

The first layer L1 may have a greater thickness than the second layer L2. The first layer L1 may have relatively high conductivity and great thickness compared to the second layer L2, thus reducing contact resistance between the first layer L1 and the cathodes CE. Accordingly, a common cathode voltage may be uniformly provided to light-emitting regions PXA-R, PXA-G, and PXA-B.

According to some embodiments of the present disclosure, the light-emitting patterns EL may be patterned and deposited in units of pixel due to the tip portion TIP defined in the partition wall PW. That is, the light-emitting patterns EL may be formed in common on a whole surface of the base layer BS using an open mask, and may be easily patterned and deposited in units of pixel due to the partition wall PW.

Meanwhile, when light-emitting patterns are patterned using a fine metal mask (FMM), a separate supporting spacer protruding from a conductive partition wall may need to be provided so as to support the fine metal mask. In addition, because the fine metal mask is spaced apart by a height of the spacer and the partition wall from a base surface on which patterning is performed, there may be a limitation in implementing high resolution. In addition, because the fine metal mask is in contact with the spacer, foreign substance may remain on the spacer after a process of patterning the light-emitting patterns, or the spacer may be damaged by being scratched by the fine metal mask. Accordingly, a defective display panel may be formed.

According to some embodiments, physical separation between the light-emitting elements OL-R, OL-G, and OL-B may be easily achieved by including the partition wall PW including a conductive material. Accordingly, current leakage between adjacent light-emitting regions PXA-R, PXA-G, and PXA-B, error in the operation thereof, or the like may be prevented or reduced, and it may be possible for each of the light-emitting elements OL-R, OL-G, and OL-B to be independently operated.

In particular, the light-emitting patterns EL may be sequentially patterned without a mask being in contact with an inner component in the display region DA (see FIG. 1A), and thus defect rate may be reduced, and the display panel DP having relatively improved process reliability may be provided. In addition, because patterning may be possible even if a separate supporting spacer protruding from the partition wall PW is not provided, an area of the light-emitting regions PXA-R, PXA-G, and PXA-B may be relatively reduced, and thus the display panel DP which facilitates implementation of high resolution may be provided.

In addition, in manufacturing the display panel DP having a large area, because manufacturing a mask having a large area is skipped, process cost may be relatively reduced, and an effect of a defect that may be generated in a mask having a 1 large area may be prevented or reduced, and thus the display panel DP having relatively improved process reliability may be provided.

The encapsulation layer TFE may cover at least a portion of the partition wall PW and the light-emitting elements OL-R, OL-G, and OL-B. The encapsulation layer TFE may include capping patterns CP1, CP2, and CP3. The capping patterns CP1, CP2, and CP3 may include an inorganic material. For example, the inorganic material may include a silicon oxide layer and a silicon nitride layer. The silicon oxide layer and the silicon nitride layer may be each provided in plurality, and the silicon oxide layers and the silicon nitride layers may be alternately stacked.

Each of the capping patterns CP1, CP2, and CP3 may be located inside a corresponding partition wall opening PW-OP and cover the cathode CE. The capping patterns CP1, CP2, and CP3 may be directly located on corresponding cathodes CE and may protect the cathodes CE in a subsequent process. The capping patterns CP1, CP2, and CP3 may each cover a side surface of the partition wall PW exposed from the cathode CE.

According to some embodiments of the present disclosure, an organic pattern OP located on the partition wall PW may be included. More specifically, the organic pattern OP may be located on the second layer L2 (an upper layer) and in contact with an upper surface of the second layer L2. The organic pattern OP and the light-emitting patterns EL may include the same material. That is, the organic pattern OP may be defined as a portion disconnected from the light-emitting patterns EL by the partition wall PW during a process of forming the light-emitting patterns EL. In this specification, the organic pattern OP and the light-emitting patterns EL may be defined as a light-emitting organic layer.

According to some embodiments, the light-emitting organic layer may include a hole transport region, an emission layer, and an electron transport region as a functional layer. According to some embodiments, the emission layer may have a single-layered structure or a structure in which a plurality of layers are stacked.

The hole transport region may be located between the anode AE and the emission layer. The hole transport region may include a hole injection layer and a hole transport layer. However, embodiments of the present disclosure are not limited thereto, and either the hole injection layer or the hole transport layer may be omitted, or at least one of an emission auxiliary layer or an electron blocking layer may be further included in addition to the hole injection layer or the hole transport layer.

The hole transport region may have a single-layered structure including a single material, a single-layered structure including a plurality of different materials, or a multi-layered structure including a plurality of layers including a plurality of different materials.

The electron transport region may be located between the emission layer and the cathode CE. The electron transport region may include at least one of an electron transport layer or an electron injection layer, but embodiments of the present disclosure are not limited thereto. The electron transport region may further include a hole blocking layer in addition to the electron transport layer and the electron injection layer. The electron transport region may have a single-layered structure including a single material, a single-layered structure including a plurality of different materials, or a multi-layered structure including a plurality of layers including a plurality of different materials.

According to some embodiments, the light-emitting organic layer may have liquid repellency. Accordingly, the organic pattern OP located on the partition wall PW may have liquid repellency. The organic pattern OP may cover the upper surface and a side surface of the second layer L2.

According to some embodiments, the capping patterns CP1, CP2, and CP3 may each expose an upper surface of the organic pattern OP. The capping patterns CP1, CP2, and CP3 may each cover a side surface of the organic pattern OP.

The color control layer CCL may be located on the encapsulation layer TFE. A first color control pattern CCP-R may be located on the capping pattern CP2 1 covering the cathode CE and the partition wall opening PW-OP. A portion of the first color control pattern CCP-R may be located on the organic pattern OP located on the partition wall PW.

A second color control pattern CCP-G may be located on the capping pattern CP3 covering the cathode CE and the partition wall opening PW-OP. A portion of the second color control pattern CCP-G may be located on the organic pattern OP located on the partition wall PW.

A third color control pattern CCP-B may be located on the capping pattern CP1 covering the cathode CE and the partition wall opening PW-OP. A portion of the third color control pattern CCP-B may be located on the organic pattern OP located on the partition wall PW.

At least a portion of the plurality of color control patterns CCP-R, CCP-G, and CCP-B may change an optical property of source light. According to some embodiments, at least a portion of the color control patterns CCP-R, CCP-G, and CCP-B may include a quantum dot that changes an optical property of source light.

According to some embodiments, the first color control pattern CCP-R may include a quantum dot for changing an optical property of source light. The quantum dot included in the first color control pattern CCP-R may convert source light into light having a different wavelength. For example, in the first color control pattern CCP-R overlapping a first light-emitting region PXA-R, the quantum dot may convert the source light into red light.

As used herein, a quantum dot refers to a crystal of a semiconductor compound. The quantum dot may emit light having various emission wavelengths according to a size of the crystal. The quantum dot may emit light having various emission wavelengths according to adjustment of an element ratio in the quantum dot compound.

A diameter of the quantum dot may be, for example, about 1 nm to about 10 nm. The quantum dot may be synthesized by a wet chemical process, a metal organic chemical vapor deposition process, a molecular beam epitaxy process, a process similar thereto, or the like.

The wet chemical process in a quantum dot manufacturing process is a method of mixing a precursor material with an organic solvent and then growing a quantum dot particle crystal. When the quantum dot particle crystal grows, the organic solvent may naturally serve as a dispersant coordinated on a surface of the quantum dot crystal and control growth of the particle crystal. Thus, through the wet chemical process which is a low-cost process and is easier to perform than a vapor deposition method such as metal organic chemical vapor deposition (MOCVD) or molecular beam epitaxy (MBE), growth of a quantum dot particle may be controlled.

A core of the quantum dot may be selected from a group II-VI compound, a group III-V compound, a group III-VI compound, a group I-III-VI compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Meanwhile, a group II-VI semiconductor compound may further include a group I metal and/or a group IV element. A group I-II-VI compound may be selected from CuSnS or CuZnS, and ZnSnS, etc. may be selected as a group II-IV-VI compound. A group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The group III-VI compound may include a binary compound such as In₂S₃ and In₂Se₃, a ternary compound such as InGaS₃ and InGaSe₃, or any combination thereof.

The group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ and CuInGaS₂.

The group III-V compound may be selected from the group consisting of a binary compound selected from the group consisting of GaN, GaP, GaAs, GaSb, AlN, AIP, AIAs, AISb, InN, InP, InAs, InSb, and a mixture thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and a mixture thereof, and a quaternary compound selected from the group consisting of GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, and a mixture thereof. Meanwhile, the group III-V compound may further include a group II metal. For example, InZnP, etc. may be selected as a group III-II-V compound.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof.

An example of a group II-IV-V semiconductor compound may include a ternary compound selected from the group consisting of ZnSnP, ZnSnP₂, ZnSnAs₂, ZnGeP₂, ZnGeAs₂, CdSnP₂, and CdGeP₂, and a mixture thereof.

The group IV element may be selected from the group consisting of Si, Ge, and a mixture thereof. The group IV compound may include a binary compound selected from the group consisting of SiC, SiGe, and a mixture thereof.

Each element included in a multi-element compound such as a binary compound, a ternary compound, and a quaternary compound may be present in a particle with a uniform concentration or a non-uniform concentration. That is, a formula expressing the quantum dot may mean types of elements included in a quantum dot compound, and an element ratio in the compound may be different. For example, AgInGaS₂ may mean AgInₓGa₁₋ₓS₂ (x is a real number between 0 and 1).

Here, the binary compound, the ternary compound, or the quaternary compound may be present in a particle with a uniform concentration, or may be present in the same particle with partially different concentration distributions. In addition, the quantum dot may have a core/shell structure in which one quantum dot surrounds another quantum dot. The core/shell structure may have a concentration gradient in which a concentration of elements present in the shell decreases toward the core.

In some embodiments, the quantum dot may have a core-shell structure including a core having the nanocrystal described above and a shell surrounding the core. The shell of the quantum dot may serve as a protective layer for maintaining semiconductor characteristics by preventing or reducing chemical modification of the core and/or serve as a charging layer for imparting electrophoretic characteristics to the quantum dot. The shell may be a single layer or multiple layers. An example of the shell of the quantum dot may include a metal or non-metal oxide, a semiconductor compound, a combination thereof, or the like.

For example, an example of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but embodiments of the present disclosure are not limited thereto.

In addition, an example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, etc., but embodiments of the present disclosure are not limited thereto.

The quantum dot may have a full width of half maximum (FWHM) of an emission wavelength spectrum of about 45 nm or less, preferably about 40 nm or less, and more preferably about 30 nm or less, and within this range, color purity or color reproducibility may be relatively improved. In addition, light emitted through such a quantum dot is emitted in all directions, so that a wide viewing angle may be relatively improved.

In addition, a shape of the quantum dot is not particularly limited to a shape commonly used in the field, but more specifically, the quantum dot may have a shape of a spherical, pyramidal, multi-arm, or cubic nanoparticle, nanotube, nanowire, nanofiber, nanoplatelet particle, etc.

Because an energy band gap may be controlled by adjusting a size of the quantum dot or adjusting an element ratio in a quantum dot compound, light of various wavelength bands may be obtained in a quantum dot emission layer. Thus, by using the quantum dots (having different sizes or having a varied element ratio in a quantum dot compound) as described above, a light-emitting element which emits light having various wavelengths may be implemented. Specifically, adjustment of a size of the quantum dot or an element ratio in a quantum dot compound may be selected to emit red, green, and/or blue light. In addition, the quantum dots may be configured such that beams of light having various colors are combined to emit white light.

According to some embodiments, the quantum dot included in the first color control pattern CCP-R overlapping the first light-emitting region PXA-R may emit red light. As a particle size of a quantum dot decreases, light in a shorter wavelength 1 region may be emitted. For example, in quantum dots having the same core, a particle size of a quantum dot which emits green light may be smaller than a particle size of a quantum dot which emits red light. In addition, in quantum dots having the same core, a particle size of a quantum dot which emits blue light may be smaller than a particle size of a quantum dot which emits green light. However, embodiments of the present disclosure are not limited thereto, and even in quantum dots having the same core, a particle size may be adjusted according to a material for forming a shell, a thickness of the shell, and the like.

Meanwhile, in a case in which quantum dots have various emission colors such as blue, red, and green, quantum dots having different emission colors may have different core materials.

The color control patterns CCP-R, CCP-G, and CCP-B of the color control layer CCL may include a scatterer. The first color control pattern CCP-R may include the quantum dot which converts source light into red light and a scatterer which scatters light.

The scatterer may be an inorganic particle. For example, the scatterer may include at least one of TiO₂, ZnO, Al₂O₃, SiO₂, or hollow silica. The scatterer may include any one of TiO₂, ZnO, Al₂O₃, SiO₂, or hollow silica, or a mixture of two or more materials selected from among TiO₂, ZnO, Al₂O₃, SiO₂, and hollow silica.

Meanwhile, the description of the first color control pattern CCP-R made above may be partially equally applied to the second color control pattern CCP-G.

According to some embodiments, the second color control pattern CCP-G may include a quantum dot for changing an optical property of source light. The quantum dot included in the second color control pattern CCP-G may convert source light into light having a different wavelength. For example, in the second color control pattern CCP-G overlapping a second light-emitting region PXA-G, the quantum dot may convert the source light into green light.

In addition, the third color control pattern CCP-B overlapping a third light-emitting region PXA-B may not include a quantum dot. However, embodiments of the present disclosure are not limited thereto, and the third color control pattern CCP-B may include a quantum dot which partially wave-converts source light provided from a third light-emitting element OL-B.

The second color control pattern CCP-G and the third color control pattern CCP-B may also further include a scatterer. For example, according to some embodiments, the first color control pattern CCP-R may include a first quantum dot and a scatterer, the second color control pattern CCP-G may include a second quantum dot and a scatterer, and the third color control pattern CCP-B may not include a quantum dot and may include a scatterer.

The second color control pattern CCP-G and the third color control pattern CCP-B may each also include a base resin for dispersing a quantum dot and a scatterer.

As illustrated in FIG. 6, the first color control pattern CCP-R and the third color control pattern CCP-B located on the organic pattern OP may be spaced apart from each other on the organic pattern OP. In addition, the first color control pattern CCP-R and the second color control pattern CCP-G located on the organic pattern OP may be spaced apart from each other on the organic pattern OP.

Thus, an upper surface of the organic pattern OP may include a first portion O-S1 (another portion) exposed from different color control patterns and a second portion O-S2 (one portion) being in contact with different color control patterns. As described above, the organic pattern OP may have liquid repellency, and thus different color control patterns may be spaced apart from each other on the upper surface of the organic pattern OP.

The passivation layer PL may be located on the color control layer CCL. The passivation layer PL may cover the color control patterns CCP-R, CCP-G, and CCP-B. According to some embodiments, the passivation layer PL may be in contact with the first portion O-S1 of the upper surface of the organic pattern OP exposed from different color control patterns CCP-R, CCP-G, and CCP-B. According to some embodiments, the passivation layer PL may include an inorganic material. However, embodiments of the present disclosure are not limited thereto, and the passivation layer PL may include an organic material.

The color filter layer OSL may be located on the passivation layer PL. The color filter layer OSL may include a black matrix BM and color filter patterns CF-R, CF-G, and CF-B.

The black matrix BM may be directly located on the passivation layer PL. That is, the black matrix BM and the passivation layer PL may be formed through a continuous process. The black matrix BM may include an inorganic light blocking material or an organic light blocking material including a black pigment or black dye. The black matrix BM may include light blocking openings BM-OP overlapping the partition wall openings PW-OP. The light blocking openings BM-OP may be formed by penetrating the black matrix BM.

The color filter patterns CF-R, CF-G, and CF-B may be each located inside a corresponding light blocking opening BM-OP.

The color filter patterns CF-R, CF-G, and CF-B each transmit light in a specific wavelength range and block light outside the wavelength range. According to some embodiments, a first color filter pattern CF-R may be a red filter which transmits red light, a second color filter pattern CF-G may be a green filter which transmits green light, and a third color filter pattern CF-B may be a blue filter which transmits blue light.

The color filter patterns CF-R, CF-G, and CF-B each include a polymer photosensitive resin and a colorant. The colorant may include a pigment or dye. The first color filter pattern CF-R may include a red pigment or red dye, the second color filter pattern CF-G may include a green pigment or green dye, and the third color filter pattern CF-B may include a blue pigment or blue dye. Meanwhile, according to some embodiments, the third color filter pattern CF-B may not include a pigment or dye.

The first to third color filter patterns CF-R, CF-G, and CF-B may be located to respectively correspond to the first light-emitting region PXA-R, the second light-emitting region PXA-G, and the third light-emitting region PXA-B. In addition, the first to third color filter pattern CF-R, CF-G, and CF-B may be arranged to respectively overlap the first to third color control patterns CCP-R, CCP-G, and CCP-B.

The window panel WD may be located on the color filter layer OSL. The window panel WD and the color filter layer OSL may be bonded to each other by the adhesive layer AD.

In the display device ED according to some embodiments of the present disclosure, the cathodes CE included in the light-emitting elements OL-R, OL-G, and OL-B may be in contact with the first layer L1 (a lower layer) of the partition wall PW, the first layer L1 having relatively high conductivity and great thickness, and thus contact resistance between the partition wall PW and the cathodes CE may be relatively reduced. Accordingly, a common cathode voltage may be uniformly provided to the light-emitting regions PXA-R, PXA-G, and PXA-B.

In addition, the light-emitting patterns EL respectively included in pixels may be individually separated by the partition wall PW, and thus generation of color shift caused by current leakage in a low grayscale region may be prevented or reduced.

In addition, deposition may be performed through an open mask using the partition wall PW without using a fine metal mask (FMM) to form the light-emitting patterns EL, and thus physical separation between the light-emitting elements OL-R, OL-G, and OL-B may be easily achieved. Accordingly, the display device ED that is manufactured through a simplified manufacturing method may be provided.

In addition, the light-emitting elements OL-R, OL-G, and OL-B may be individually encapsulated through the capping patterns CP1, CP2, and CP3, and thus the display panel DP having ensured reliability may be provided.

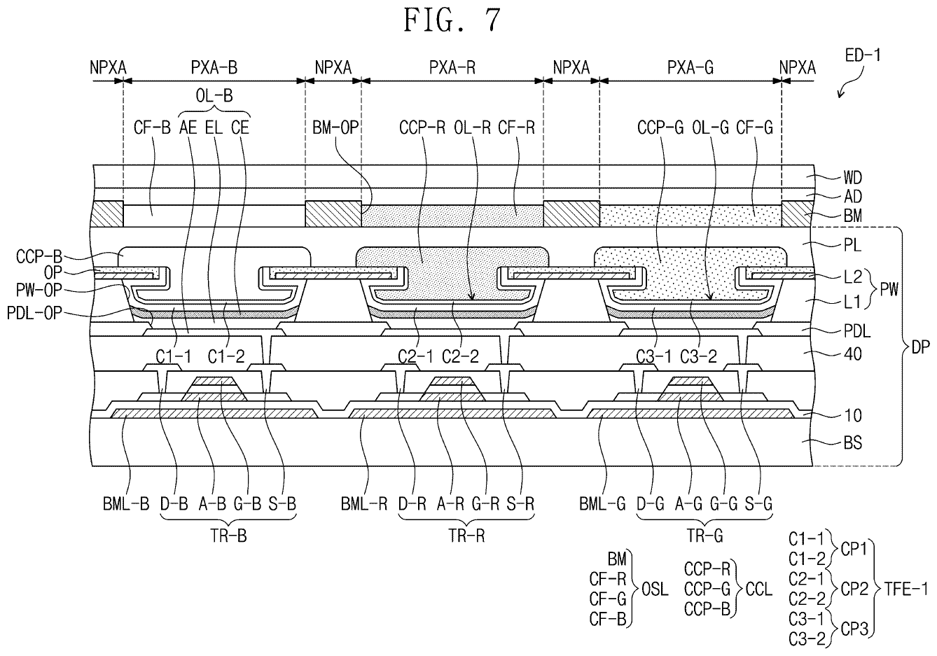

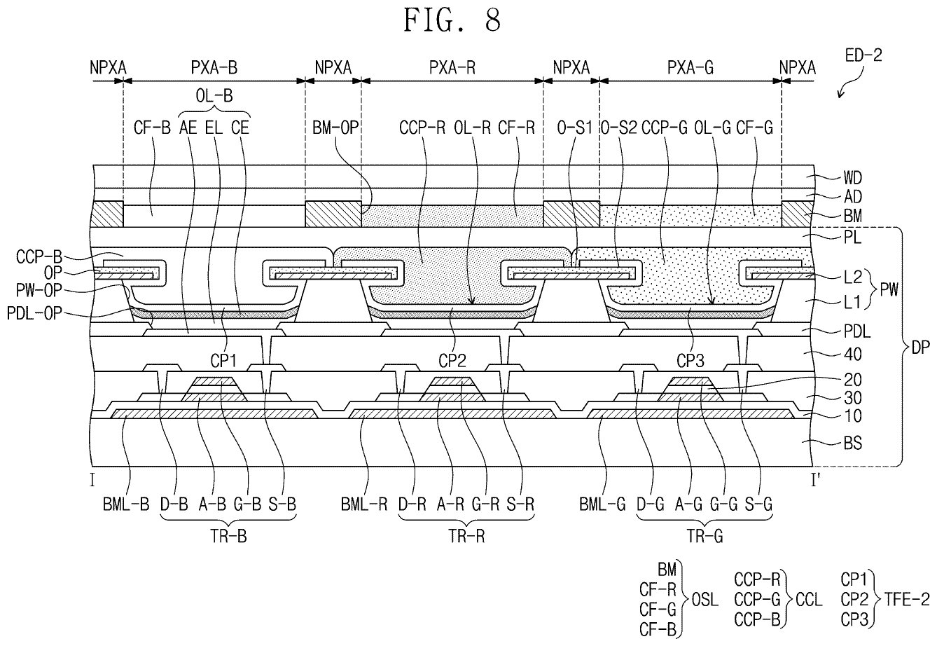

FIG. 7 is a cross-sectional view of a display device according to some embodiments of the present disclosure. FIG. 8 is a cross-sectional view of a display 1 device according to some embodiments of the present disclosure. A component same as/similar to the component described with reference to FIGS. 5 and 6 will be denoted as the same/similar reference numerals or symbols, and description overlapping with the above description will not be provided.

Referring to FIG. 7, a display device ED-1 according to some embodiments may include a display panel DP, a color filter layer OSL, and a window panel WD. An adhesive layer AD may be located between the color filter layer OSL and the window panel WD.

The display panel DP may include a base layer BS, the circuit element layer DP-CL (see FIG. 2A) located on the base layer BS, the display element layer DP-OLED (see FIG. 2A) located on the circuit element layer DP-CL (see FIG. 2A), and an encapsulation layer TFE-1 covering the display element layer DP-OLED (see FIG. 2A).

The circuit element layer DP-CL (see FIG. 2A) may include insulating layers 10 to 40 located on the base layer BS, transistors TR-R, TR-G, and TR-B, and light blocking patterns BML-R, BML-G, and BML-B.

The display element layer DP-OLED (see FIG. 2A) may include a pixel-defining layer PDL, a partition wall PW, light-emitting elements OL-R, OL-B, and OL-G, the encapsulation layer TFE-1, a color control layer CCL, and a passivation layer PL. According to some embodiments, an organic pattern OP located on the partition wall PW may be included.

The encapsulation layer TFE-1 according to some embodiments may include first to third capping patterns CP1, CP2, and CP3. The first capping pattern CP1 may be located inside a partition wall opening PW-OP in which a third light-emitting element OL-B is located. The first capping pattern CP1 may include a first pattern C1-1 and a second pattern C1-2. The first pattern C1-1 may cover a cathode CE of the third light-emitting element OL-B and a side surface of the partition wall PW defining the partition wall opening PW-OP in which the cathode CE is located. The second pattern C1-2 may be located on the first pattern C1-1. A portion of a third color control pattern CCP-B may be in contact with the second pattern C1-2.

The second capping pattern CP2 may be located inside a partition wall opening PW-OP in which a first light-emitting element OL-R is located. The second capping pattern CP2 may include a first pattern C2-1 and a second pattern C2-2. The first pattern C2-1 may cover a cathode CE of the first light-emitting element OL-R and a side surface of the partition wall PW defining the partition wall opening PW-OP in which the cathode CE is located. The second pattern C2-2 may be located on the first pattern C2-1. A portion of a first color control pattern CCP-R may be in contact with the second pattern C2-2.

The third capping pattern CP3 may be located inside a partition wall opening PW-OP in which a second light-emitting element OL-G is located. The third capping pattern CP3 may include a first pattern C3-1 and a second pattern C3-2. The first pattern C3-1 may cover a cathode CE of the second light-emitting element OL-G and a side surface of the partition wall PW defining the partition wall opening PW-OP in which the cathode CE is located. The second pattern C3-2 may be located on the first pattern C3-1. A portion of a second color control pattern CCP-G may be in contact with the second pattern C3-2.

The first patterns and the second patterns included in the first to third capping patterns CP1, CP2, and CP3 may include an inorganic material. According to some embodiments, because inorganic layers are stacked, the first to third capping patterns CP1, CP2, and CP3 may each effectively protect the light-emitting element from moisture and oxygen.

Referring to FIG. 8, a display device ED-2 according to some embodiments may include a display panel DP, a color filter layer OSL, and a window panel WD. An adhesive layer AD may be located between the color filter layer OSL and the window panel WD.

The display panel DP may include a base layer BS, the circuit element layer DP-CL (see FIG. 2A) located on the base layer BS, the display element layer DP-OLED (see FIG. 2A) located on the circuit element layer DP-CL (see FIG. 2A), and an encapsulation layer TFE-2 covering the display element layer DP-OLED (see FIG. 2A).

The circuit element layer DP-CL (see FIG. 2A) may include insulating layers 10 to 40 located on the base layer BS, transistors TR-R, TR-G, and TR-B, and light blocking patterns BML-R, BML-G, and BML-B.

The display element layer DP-OLED (see FIG. 2A) may include a pixel-defining layer PDL, a partition wall PW, light-emitting elements OL-R, OL-B, and OL-G, the encapsulation layer TFE-2, a color control layer CCL, and a passivation layer PL. According to some embodiments, an organic pattern OP located on the partition wall PW may be included.

The encapsulation layer TFE-2 according to some embodiments may include first to third capping patterns CP1, CP2, and CP3. The first capping pattern CP1 may be located inside a partition wall opening PW-OP in which a third light-emitting element OL-B is located. A portion of the first capping pattern CP1 may cover a portion of the organic pattern OP located on a second layer L2.

The second capping pattern CP2 may be located inside a partition wall opening PW-OP in which a first light-emitting element OL-R is located. A portion of the second capping pattern CP2 may cover a portion of the organic pattern OP located on the second layer L2.

The third capping pattern CP3 may be located inside a partition wall opening PW-OP in which a second light-emitting element OL-G is located. A portion of the third capping pattern CP3 may cover a portion of the organic pattern OP located on the second layer L2.

An upper surface of the organic pattern OP may include a first portion O-S1 exposed from different capping patterns and a second portion O-S2 being in contact 1 with different capping patterns. Different color control patterns CCP-R, CCP-G, and CCP-B may be in contact with each other on the first portion O-S1.

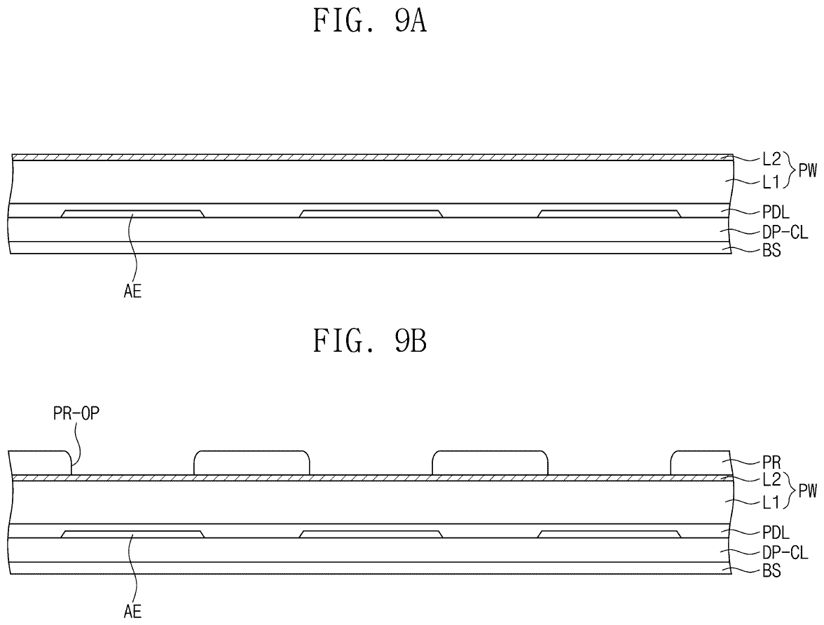

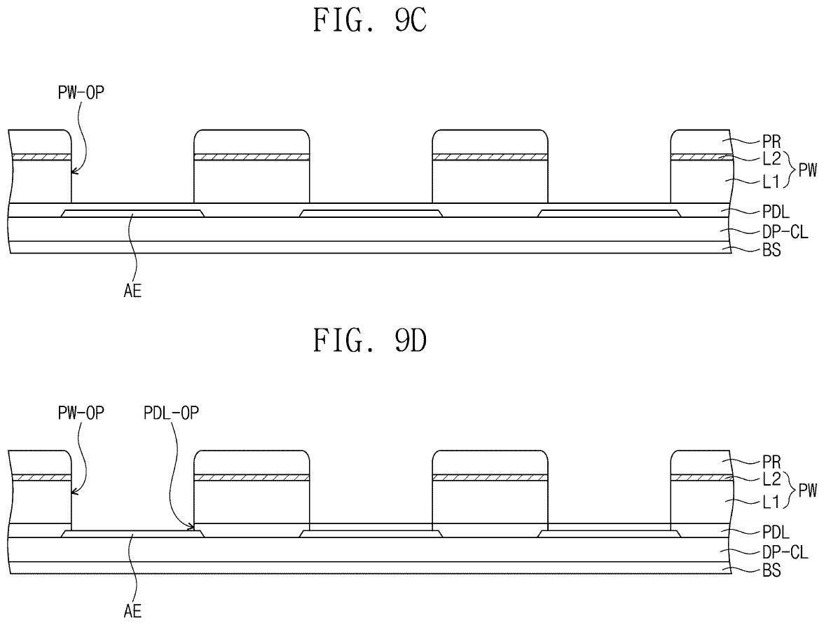

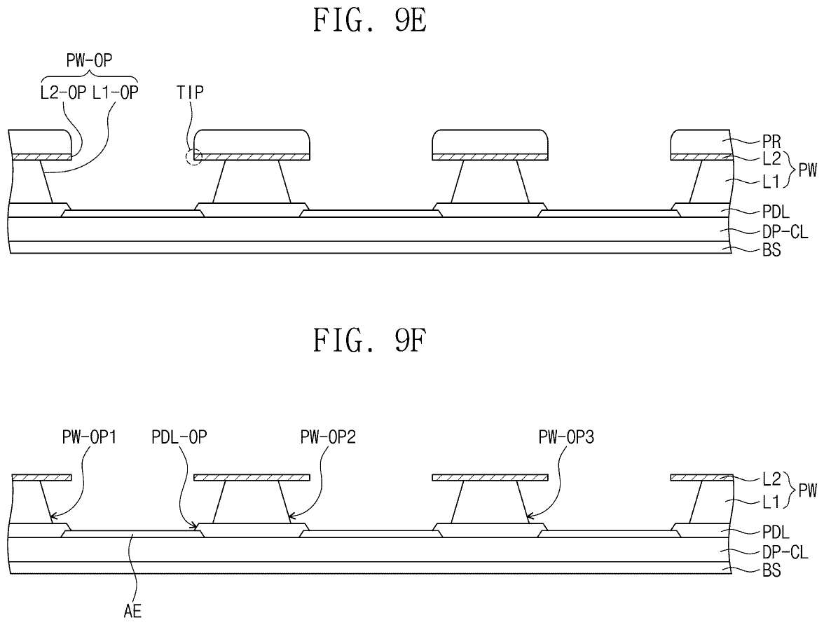

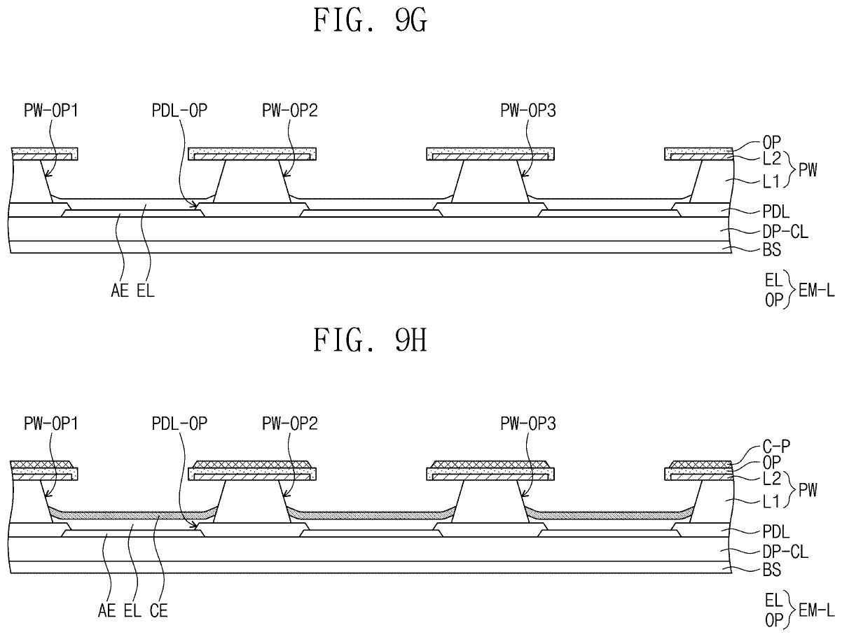

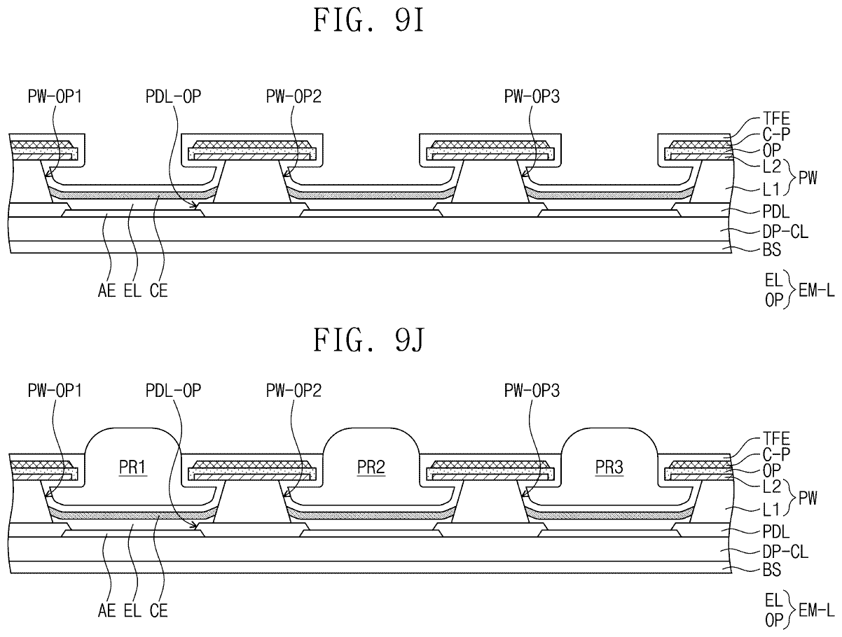

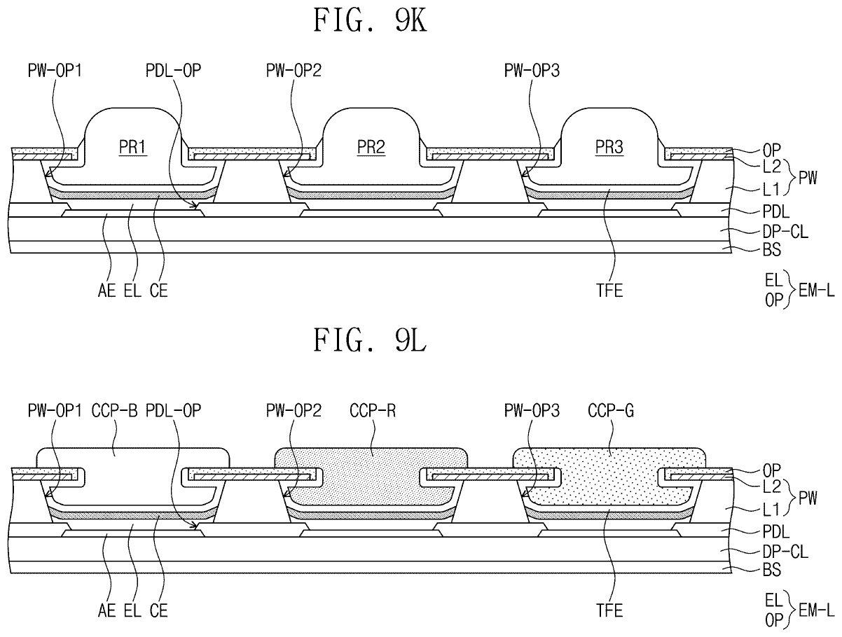

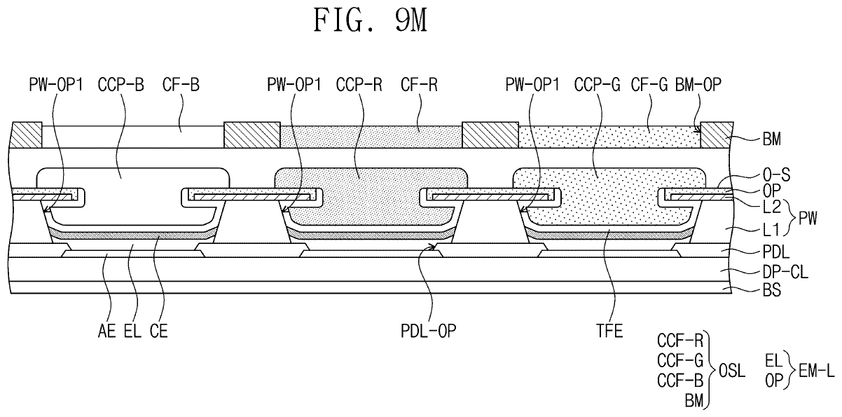

FIGS. 9A to 9M are cross-sectional views of a manufacturing method of a display device according to some embodiments of the present disclosure. A component same as/similar to the component described with reference to FIGS. 1A to 6 will be denoted as the same/similar reference numerals or symbols, and description overlapping with the above description will not be provided.

A manufacturing method of a display device according to some embodiments of the present disclosure may include forming, on a base layer, a pixel-defining layer having light-emitting openings defined therein, the light-emitting openings exposing first electrodes, forming, on the pixel-defining layer, a partition wall having partition wall openings defined therein, the partition wall openings overlapping the light-emitting openings, forming a light-emitting organic layer on the first electrodes and the partition wall, forming a second electrode on the light-emitting organic layer, forming an encapsulation layer covering the second electrode and the partition wall openings, forming photoresist patterns on the encapsulation layer overlapping the partition wall openings, removing the encapsulation layer located on the partition wall, exposing the light-emitting organic layer located on the partition wall by removing the second electrode located on the partition wall, and forming color control patterns inside the partition wall openings. Hereinafter, a manufacturing method of a display device according to some embodiments of the present disclosure will be described in more detail with reference to FIGS. 9A to 9M.

Referring to FIG. 9A, the manufacturing method of a display device according to some embodiments may include providing a work substrate. As used herein, the work substrate may be defined as a state in which a base layer BS, a circuit element layer DP-CL, anodes AE, a pixel-defining layer PDL, and a partition wall PW are formed.

The circuit element layer DP-CL may be formed through a manufacturing process for a typical circuit element, the process including forming an insulating layer, a semiconductor layer, and a conductive layer through coating, deposition, etc., selectively patterning the insulating layer, the semiconductor layer, and the conductive layer through photolithography and etching process, and forming a semiconductor pattern, a conductive pattern, a signal line, and the like.

The anodes AE may be spaced apart from each other on the circuit element layer DP-CL. The pixel-defining layer PDL may include an inorganic material and cover the anodes AE.

The partition wall PW may be formed on the pixel-defining layer PDL. The partition wall PW may include a first layer L1 (a lower layer) and a second layer L2 (an upper layer) located on the first layer L1. The first layer L1 may be in contact with the pixel-defining layer PDL. The first layer L1 and the second layer L2 may include different conductive materials. A thickness of the first layer L1 may be greater than a thickness of the second layer L2.

Then, referring to FIG. 9B, forming a photoresist layer PR on the work substrate may be included. The photoresist layer PR may include photo openings PR-OP. The photo openings PR-OP may be formed by forming the photoresist layer PR on the partition wall PW and then patterning the photoresist layer PR through a photo mask. The photo openings PR-OP may each overlap the anode AE.

Then, referring to FIG. 9C, the manufacturing method of a display device according to some embodiments may include forming partition wall openings PW-OP in the partition wall PW.

The forming of the partition wall openings PW-OP in the partition wall PW may be performed through a dry etching process using the photoresist layer PR as a mask. The partition wall openings PW-OP having a first width may be formed by removing the first and second layers L1 and L2 through the etching process. The partition wall openings PW-OP may each overlap the anode AE. In this etching 1 process, an inner surface of the first layer L1 and an inner surface of the second layer L2 which define each partition wall opening PW-OP may be aligned with each other.

Thereafter, referring to FIG. 9D, forming light-emitting openings PDL-OP in the pixel-defining layer PDL may be included.

The forming of the light-emitting openings PDL-OP in the pixel-defining layer PDL may be performed through a dry etching process. The light-emitting openings PDL-OP and the partition wall openings PW-OP may overlap each other in one-to-one manner. Thus, the partition wall openings PW-OP may each overlap the anode AE.

Thereafter, referring to FIG. 9E, the manufacturing method of a display device according to some embodiments may include forming the partition wall openings PW-OP having a second width, which is greater than the first width, in the partition wall PW through an etching process. According to some embodiments, the etching process may be performed through wet etching.

The wet etching process may be performed in an environment in which etch selectivity between the first and second layers L1 and L2 is high. Accordingly, an inner surface of the partition wall PW defining one partition wall opening PW-OP may have an under-cut shape in a cross-sectional view.

Specifically, an etch rate of the first layer L1 with respect to etching solution may be greater than an etch rate of the second layer L2, and thus the first layer L1 may be mainly etched. Accordingly, an inner surface of the first layer L1 may be formed to be further inwardly recessed compared to an inner surface of the second layer L2.

The partition wall opening PW-OP may be formed because a first opening L1-OP defined in the first layer L1 and a second opening L2-OP defined in the second layer L2 may overlap each other. Here, a side surface of the second layer L2 defining the second opening L2-OP may further protrude in a direction toward a center of the partition wall opening PW-OP than a side surface of the first layer L1 defining the first 1 opening L1-OP, and a portion of the second layer L2, the portion protruding from the first layer L1, may form a tip portion TIP in the partition wall PW.

Thereafter, referring to FIG. 9F, the manufacturing method of a display device according to some embodiments may include removing the photoresist layer PR. Accordingly, the second layer L2 may be exposed. After the process described with reference to FIGS. 9A to 9F, first to third partition wall openings PW-OP1, PW-OP2, and PW-OP3 respectively overlapping the anodes AE may be formed. Thereafter, referring to FIG. 9G, the manufacturing method of a display device according to some embodiments may include forming an emission layer EL-L. The emission layer EL-L may include an organic light-emitting material. The emission layer EL-L according to some embodiments of the present disclosure may have liquid repellency. The emission layer EL-L may be formed on a whole surface of the partition wall PW through an open mask.

Here, the emission layer EL-L may be formed individually inside each of the first to third partition wall openings PW-OP1, PW-OP2, and PW-OP3 due to the tip portion TIP of the partition wall PW. Accordingly, among the emission layer EL-L, portions respectively located inside the first to third partition wall openings PW-OP1, PW-OP2, and PW-OP3 may be defined as light-emitting patterns EL, and a portion disconnected from the light-emitting patterns EL by the partition wall PW and located on the partition wall PW may be defined as an organic pattern OP. Thus, the light-emitting patterns EL and the organic pattern OP may include the same material, and the organic pattern OP may be located on the partition wall PW and have liquid repellency.

Thereafter, referring to FIG. 9H, the manufacturing method of a display device according to some embodiments may include forming a cathode CE (a second electrode). The cathode CE may be formed on the emission layer EL-L through an open mask. The cathode CE may be also divided into portions located on the light-1 emitting patterns EL due to the tip portion TIP of the partition wall PW and a dummy portion C-P located on the organic pattern OP.

The cathodes CE located on the light-emitting patterns EL may be in contact with a side surface of the partition wall PW, and accordingly, the cathodes CE spaced apart from each other in the first to third partition wall openings PW-OP1, PW-OP2, and PW-OP3 may be electrically connected by the partition wall PW including a conductive material.

Thereafter, referring to FIG. 9I, the manufacturing method of a display device according to some embodiments may include forming an encapsulation layer TFE on the cathode CE. The forming of the encapsulation layer TFE may be performed through a chemical vapor deposition (CVD) process, and a single-layered inorganic layer or multi-layered inorganic layers may be stacked. The encapsulation layer TFE may cover the partition wall PW, a side surface of the partition wall PW defining the first to third partition wall openings PW-OP1, PW-OP2, and PW-OP3, and the cathodes CE. Accordingly, the light-emitting patterns EL may be protected from moisture and oxygen.

Thereafter, referring to FIG. 9J, the manufacturing method of a display device according to some embodiments may include forming first to third photoresist patterns PR1, PR2, and PR3. The first to third photoresist patterns PR1, PR2, and PR3 may be respectively located inside corresponding first to third partition wall openings PW-OP1, PW-OP2, and PW-OP3.

Thereafter, referring to FIG. 9K, the manufacturing method of a display device according to some embodiments may include removing the encapsulation layer TFE and the dummy portion C-P located on the partition wall PW. The dummy portion C-P located on the partition wall PW may be removed through an etching process using the first to third partition wall openings PW-OP1, PW-OP2, and PW-OP3 as a mask. The etching process through which the dummy portion C-P is removed may be performed through a wet etching process. A process through which the encapsulation layer TFE located on the partition wall PW is removed may be performed through a dry etching process. When the encapsulation layer TFE and the dummy portion C-P located on the partition wall PW are removed, the organic pattern OP located on an upper surface of the partition wall PW may be exposed. As described above, the organic pattern OP may have liquid repellency.

Thereafter, referring to FIG. 9L, the manufacturing method of a display device according to some embodiments may include forming first to third color control patterns CCP-R, CCP-G, and CCP-B in the first to third partition wall openings PW-OP1, PW-OP2, and PW-OP3, respectively. Among the first to third color control patterns CCP-R, CCP-G, and CCP-B, the first and second color control patterns CCP-R and CCP-G may include a quantum dot, and the third color control pattern CCP-B may not include a quantum dot. The forming of the first to third color control patterns CCP-R, CCP-G, and CCP-B may be performed through an inkjet process.

Thereafter, referring to FIG. 9M, the manufacturing method of a display device according to some embodiments may include forming a passivation layer PL on the first to third color control patterns CCP-R, CCP-G, and CCP-B and forming a color filter layer OSL on the passivation layer PL. The forming of the passivation layer PL may be performed through a chemical vapor deposition (CVD) process, and a single-layered inorganic layer or multi-layered inorganic layers may be stacked.

Light blocking openings BM-OP may be formed in a black matrix BM. In forming the black matrix BM, an inorganic light blocking material or an organic light blocking material including a black pigment or black dye may be applied to a whole surface of the passivation layer PL, and portions overlapping the first to third color control patterns CCP-R, CCP-G, and CCP-B may be patterned, and thus the light blocking openings BM-OP may be formed. Thereafter, first to third color filter patterns CF-R, CF-G, and CF-B may be respectively formed in the light blocking openings BM-OP.

In the manufacturing method of a display device according to some embodiments of the present disclosure, the emission layer EL-L may be divided into the light-emitting patterns EL through the partition wall PW, and thus a process of depositing the light-emitting patterns EL using a FMM mask may be skipped. In addition, the cathodes CE spaced apart from each other may be electrically connected through the partition wall PW, and thus contact resistance between the partition wall PW and the cathodes CE may be relatively reduced.

In a display device according to some embodiments of the present disclosure, cathodes included in light-emitting elements may be in contact with a partition wall, and thus contact resistance between the partition wall and the cathodes may be relatively reduced.

In addition, light-emitting patterns respectively included in pixels may be individually separated by the partition wall, and thus generation of color shift caused by current leakage in a low grayscale region may be prevented or reduced.

In addition, deposition may be performed through an open mask using the partition wall to form the light-emitting patterns, and thus physical separation between the light-emitting elements may be easily achieved. Accordingly, a display device that is manufactured through a simplified manufacturing method may be provided.

Although the embodiments of the present disclosure have been described, it is understood that the embodiments according to the present disclosure should not be limited to these embodiments, but various changes and modifications may be made by one ordinary skilled in the art within the spirit and scope of embodiments according to the present disclosure as hereinafter claimed.

Therefore, the technical scope of embodiments according to the present disclosure is not limited to the contents described in the detailed description of the specification but should be determined by the appended claims, and their equivalents.

What is claimed is:

1. A display device comprising:
a base layer including light-emitting regions and a non-light-emitting region adjacent to the light-emitting regions;
a pixel-defining layer including light-emitting openings respectively overlapping the light-emitting regions and on the base layer;
first to third light-emitting elements each including a first electrode in a light-emitting opening, a second electrode, and a light-emitting pattern between the first electrode and the second electrode, and configured to provide source light having a same color;
a partition wall including partition wall openings respectively overlapping the light-emitting openings and on the pixel-defining layer;
an encapsulation layer including capping patterns each inside the partition wall opening and covering the second electrode; and
a color control layer including color control patterns, which are each inside the partition wall opening and of which at least any one includes a quantum dot (QD).

2. The display device of claim 1, wherein the partition wall comprises a lower layer on the pixel-defining layer and an upper layer on the lower layer, and
the lower layer includes aluminum, and the upper layer includes titanium.

3. The display device of claim 2, further comprising an organic pattern on the upper layer,
wherein the organic pattern has liquid repellency.

4. The display device of claim 3, wherein a portion of an upper surface of the organic pattern is exposed from the color control patterns.

5. The display device of claim 4, wherein another portion of the upper surface of the organic pattern is covered with the color control patterns.

6. The display device of claim 4, further comprising a passivation layer on the partition wall and the color control layer and including an inorganic material.

7. The display device of claim 6, wherein the color control patterns are spaced apart from each other on the upper surface of the organic pattern, and
the portion of the organic pattern exposed between the color control patterns is in contact with the passivation layer.

8. The display device of claim 6, further comprising a color filter layer including a black matrix including light blocking openings overlapping the partition wall openings and color filter patterns each in a light blocking opening and overlapping the color control patterns, the color filter layer being on the passivation layer.

9. The display device of claim 8, further comprising a window on the color filter layer and an adhesive layer between the color filter layer and the window.

10. The display device of claim 3, wherein a portion of an upper surface of the organic pattern is covered with the capping patterns, and
the color control patterns are in contact with each other on another portion, exposed by the capping patterns, of the upper surface of the organic pattern.

11. The display device of claim 3, wherein the light-emitting pattern and the organic pattern comprise a same material.

12. The display device of claim 1, wherein the source light has a blue color.

13. The display device of claim 2, wherein the second electrode is electrically connected by being in contact with a side surface of the lower layer.

14. The display device of claim 1, comprising pixel circuits between the base layer and the pixel-defining layer and connected to the first to third light-emitting elements,
wherein the pixel circuits each include three transistors and a capacitor connected to the transistors.

15. The display device of claim 1, wherein the pixel-defining layer comprises an inorganic material.

16. A manufacturing method of a display device, the manufacturing method comprising:
forming, on a base layer, a pixel-defining layer having light-emitting openings defined therein, the light-emitting openings exposing first electrodes;
forming, on the pixel-defining layer, a partition wall having partition wall openings defined therein, the partition wall openings overlapping the light-emitting openings;
forming a light-emitting organic layer on the first electrodes and the partition wall;
forming a second electrode on the light-emitting organic layer;
forming an encapsulation layer covering the second electrode and the partition wall openings;
forming photoresist patterns on the encapsulation layer overlapping the partition wall openings;
removing the encapsulation layer on the partition wall;
exposing the light-emitting organic layer on the partition wall by removing the second electrode on the partition wall; and
forming color control patterns inside the partition wall openings.

17. The manufacturing method of claim 16, wherein the light-emitting organic layer on the partition wall has liquid repellency.

18. The manufacturing method of claim 16, wherein the partition wall comprises a lower layer on the pixel-defining layer and an upper layer on the lower layer, and
the lower layer includes aluminum, and the upper layer includes titanium.

19. The manufacturing method of claim 16, wherein the removing of the encapsulation layer is performed through a dry etching process, and
the removing of the second electrode is performed through a wet etching process.

20. The manufacturing method of claim 16, wherein the forming of the color control patterns is performed through an inkjet printing process.

21. A electronic device comprising:
a display panel displays an image based on input image data provided from the processor, and
a driving unit drives the display panel based on the input image data and a brightness value of the display panel,
the display panel including:
a base layer including light-emitting regions and a non-light-emitting region adjacent to the light-emitting regions;
a pixel-defining layer including light-emitting openings respectively overlapping the light-emitting regions and on the base layer;
first to third light-emitting elements each including a first electrode in a light-emitting opening, a second electrode, and a light-emitting pattern between the first electrode and the second electrode, and configured to provide source light having a same color;
a partition wall including partition wall openings respectively overlapping the light-emitting openings and on the pixel-defining layer;
an encapsulation layer including capping patterns each inside the partition wall opening and covering the second electrode; and
a color control layer including color control patterns, which are each inside the partition wall opening and of which at least any one includes a quantum dot (QD).

22. The electronic device of claim 21, wherein the partition wall comprises a lower layer on the pixel-defining layer and an upper layer on the lower layer, and
the lower layer includes aluminum, and the upper layer includes titanium.

23. The electronic device of claim 22, further comprising an organic pattern on the upper layer,
wherein the organic pattern has liquid repellency.

24. The electronic device of claim 23, wherein a portion of an upper surface of the organic pattern is exposed from the color control patterns.

25. The electronic device of claim 24, wherein another portion of the upper surface of the organic pattern is covered with the color control patterns.
